(19) United States
(12) Patent Application Publication
(10) Pub. No.: US 2026/0231722 A1
(43) Pub. Date: Aug. 6, 2026

(54) CHEMICAL MECHANICAL POLISHING DEVICE AND METHOD FOR PROCESSING WAFER USING SAME

(71) Applicant: SAMSUNG ELECTRONICS CO., LTD., Suwon-si (KR)

(72) Inventors: Heegeun KIM, Suwon-si (KR); Donghoon KWON, Suwon-si (KR)

(73) Assignee: SAMSUNG ELECTRONICS CO., LTD., Suwon-si (KR)

(21) Appl. No.: 19/279,491

(22) Filed: Jul. 24, 2025

(30) Foreign Application Priority Data
Feb. 3, 2025 (KR) 10-2025-0013361

(51) Int. Cl. H01L 21/67; B05C 5/02; B05C 11/08; B05C 13/02; B24B 37/20; H01L 21/3105

(52) U.S. Cl. CPC H10P 72/0472; B05C 5/02; B05C 11/08; B05C 13/02; B24B 37/20; H10P 95/062

(57) ABSTRACT

A chemical mechanical polishing device includes a polymer coater configured to apply a polymer liquid onto an insulating film formed on a surface of a wafer, a curer configured to form a polymer layer on the insulating film by inducing curing of the polymer liquid, a polisher configured to polish the surface of the wafer on which the polymer layer is formed, and a polymer remover configured to remove a residue of the polymer layer remaining on the polished surface of the wafer.

### CROSS-REFERENCE TO RELATED APPLICATION

This application claims priority under 35 U.S.C. § 119 to Korean Patent Application No. 10-2025-0013361, filed on Feb. 3, 2025, in the Korean Intellectual Property Office, the disclosure of which is incorporated by reference herein in its entirety.

### BACKGROUND

### 1. Field

The present disclosure relates generally to manufacturing of semiconductor wafers, and more particularly, to a chemical mechanical polishing device and a method for processing a wafer using the same.

### 2. Description of Related Art

A chemical mechanical polishing (CMP) process may be widely used as a process technology for planarizing a surface of a wafer. The CMP process may refer a technique of forming a flat surface by removing a protruding portion of a wafer surface using a polishing pad and/or chemical slurry, which may be considered as an essential step in manufacturing semiconductor devices.

However, in the polishing step of a related CMP process, the surface of the wafer may not be removed uniformly because a region having a relatively low strength on the wafer surface may be excessively removed, and/or the edge of the wafer may be worn out. Consequently, a uniform thickness of the wafer may not be achieved, which may adversely affect the reliability of devices and/or may cause deterioration in the electrical characteristics of a semiconductor. Thus, there exists a need for further improvements to chemical mechanical polishing technologies, as the need for device reliability and/or preservation of electrical characteristics of semiconductors may be constrained by the uniformity of wafer thicknesses. Improvements are presented herein. These improvements may also be applicable to other semiconductor manufacturing technologies.

### SUMMARY

According to an aspect of the present disclosure, a chemical mechanical polishing device includes a polymer coater configured to apply a polymer liquid onto an insulating film formed on a surface of a wafer, a curer configured to form a polymer layer on the insulating film by inducing curing of the polymer liquid, a polisher configured to polish the surface of the wafer on which the polymer layer is formed, and a polymer remover configured to remove a residue of the polymer layer remaining on the polished surface of the wafer.

According to an aspect of the present disclosure, a chemical mechanical polishing device includes a polymer coater configured to apply a polymer liquid onto an insulating film formed on a surface of a wafer, a curer configured to form a polymer layer on the insulating film by inducing curing of the polymer liquid, a polisher configured to polish the surface of the wafer on which the polymer layer is formed, a polymer remover configured to remove a residue of the polymer layer remaining on the polished surface of the wafer, a cleaner configured to clean the wafer from which the residue of the polymer layer has been removed, and a wafer transferor configured to transfer the wafer from the polymer coater to the curer, based on application of the polymer liquid being completed, transfer the wafer from the curer to the polisher, based on the polymer layer being formed by the curing of the polymer liquid, transfer the polished wafer from the polisher to the polymer remover, and transfer the wafer from the polymer remover to the cleaner, based on the residue of the polymer layer being removed.

According to an aspect of the present disclosure, a wafer processing method to be performed chemical mechanical polishing device includes applying, using a polymer coater of the chemical mechanical polishing device, a polymer liquid onto an insulating film formed on a surface of a wafer, forming a polymer layer on the insulating film by inducing curing of the polymer liquid using a curer of the chemical mechanical polishing device, polishing, using a polisher of the chemical mechanical polishing device, the surface of the wafer on which the polymer layer is formed, and removing, using a polymer remover of the chemical mechanical polishing device, a residue of the polymer layer remaining on the polished surface of the wafer.

The effects that may be obtained through the present disclosure may not be limited to those described above and in the description that follows. Technical effects not mentioned may be apparent to those skilled in the art from the following description.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a diagram schematically illustrating a chemical mechanical polishing device, according to an embodiment;

FIG. 2 illustrates a polymer coater, according to an embodiment;

FIG. 3 illustrates a polymer coater, according to an embodiment;

FIGS. 4A and 4B illustrate polymer coater devices, according to an embodiment;

FIG. 5 illustrates a curer, according to an embodiment;

FIG. 6 illustrates a curer, according to an embodiment;

FIG. 7 is a diagram illustrating an example in which a polymer coating process and a curing process are performed, according to an embodiment;

FIG. 8 is a diagram illustrating an example in which a polymer coating process and a curing process are performed, according to an embodiment;

FIG. 9 is a diagram illustrating an example in which a polymer coating process and a curing process are performed, according to an embodiment;

FIG. 10 illustrates a polymer remover, according to an embodiment;

FIG. 11 illustrates a polymer remover, according to an embodiment;

FIGS. 12A, 12B, 12C, and 12D are diagrams illustrating example arrangements of internal components of a chemical mechanical polishing device, according to an embodiment;

FIG. 13A is a diagram illustrating an example of a wafer processed by a chemical mechanical polishing device, according to a comparative example;

FIG. 13B is a diagram illustrating an example of a wafer processed by a chemical mechanical polishing device, according to an embodiment;

FIG. 14A is a diagram illustrating an example of a wafer processed by a chemical mechanical polishing device, according to a comparative example;

FIG. 14B is a diagram illustrating an example of a wafer processed by a chemical mechanical polishing device, according to an embodiment; and

FIG. 15 is a flowchart illustrating a wafer processing method, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order).

It is to be understood that when an element or layer is referred to as being “over,” “above,” “on,” “below,” “under,” or “beneath” another element or layer, it may be directly over, above, on, below, under, or beneath the other element or layer or intervening elements or layers may be present. In contrast, when an element is referred to as being “directly over,” “directly above,” “directly on,” “directly below,” “directly under,” or “directly beneath” another element or layer, there are no intervening elements or layers present.

The terms “upper,” “middle”, “lower”, or the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, or the like may be used to distinguish components from each other and do not limit the present disclosure. For example, the terms “first”, “second”, “third”, or the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, or the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

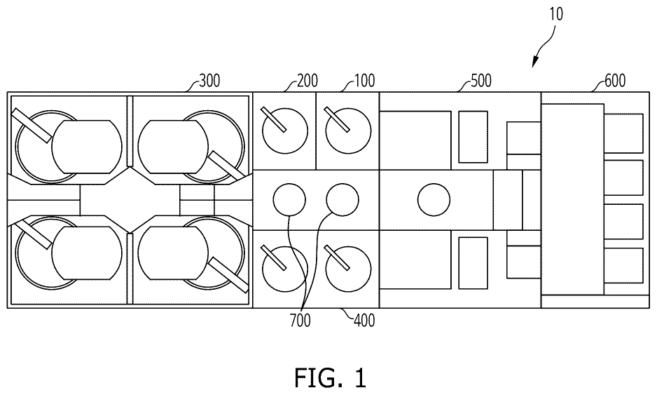

Hereinafter, with reference to FIGS. 1-3, 4A, 4B, 5-11, 12A, 12B, 12C, 12D, 13A, 13B, 14A, 14B, and 15, various embodiments of the present disclosure are described.

FIG. 1 schematically illustrates a chemical mechanical polishing device 10, according to an embodiment. The chemical mechanical polishing device 10 may include a polymer coater (or polymer coating device) 100, a curer (or curing device) 200, a polisher (or polishing device) 300, a polymer remover (or polymer remover) 400, a cleaner (or cleaning device) 500, a substrate transfer module (or equipment front end module (EFEM)) 600, and a wafer transferor (or wafer transfer device) 700.

In an embodiment, the chemical mechanical polishing device 10 may be physically implemented by analog and/or digital circuits including one or more of a logic gate, an integrated circuit, a microprocessor, a microcontroller, a memory circuit, a passive electronic component, an active electronic component, an optical component, or the like. For example, a field programmable gate array (FPGA) may be used to implement custom logic that may include the functionality of the chemical mechanical polishing device 10. As another example, one or more processors comprising processing circuitry in combination with a memory may be used to execute, individually or collectively, one or more instructions to perform the functionality of the chemical mechanical polishing device 10. That is, the one or more processors may control the overall operation of the chemical mechanical polishing device 10 and/or may control the operation of at least one of the polymer coater 100, the curer 200, the polisher 300, the polymer remover 400, the cleaner 500, the substrate transfer module 600, or the wafer transferor 700.

Alternatively or additionally, each of the components of the chemical mechanical polishing device 10 (e.g., the polymer coater 100, the curer 200, the polisher 300, the polymer remover 400, the cleaner 500, the substrate transfer module 600, and the wafer transferor 700) may be physically implemented by analog and/or digital circuits including one or more of a logic gate, an integrated circuit, a microprocessor, a microcontroller, a memory circuit, a passive electronic component, an active electronic component, an optical component, and the like. For example, an FPGA may be used to implement custom logic that may include the functionality of at least one of the components. As another example, one or more processors in combination with a memory may be used to execute, individually or collectively, one or more instructions to perform the functionality of at least one of the components. That is, the one or more processors may control the overall operation of at least one of the components.

The substrate transfer module 600 may transfer a wafer, which is to undergo wafer processing, into the chemical mechanical polishing device 10, and/or may transfer a wafer, for which the wafer processing has been completed, out of the chemical mechanical polishing device 10.

The wafer transferred into the chemical mechanical polishing device 10 may be transferred to the polymer coater 100. Although the wafer transferred into the chemical mechanical polishing device 10 may be transferred to the polymer coater 100 by the wafer transferor 700 included in the chemical mechanical polishing device 10, embodiments of the present disclosure are not limited thereto. For example, the wafer may be transferred directly to the polymer coater 100 by the substrate transfer module 600.

The polymer coater 100 may apply a polymer liquid to the wafer. The wafer transferred to the polymer coater 100 may include an insulating film on a surface (e.g., one (1) surface) thereof. The insulating film may be configured to fill a space between patterns and/or to cover an upper side of a pattern, so as to provide electrical insulation between patterns formed on the surface of the wafer, for example. The polymer coater 100 may apply a polymer liquid onto the insulating film formed on the surface of the wafer.

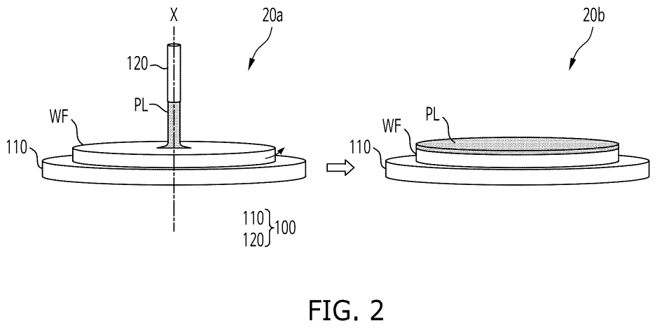

In an embodiment, the polymer coater 100 may include a plate configured to support the wafer and a nozzle configured to supply the polymer liquid. The polymer coater 100 may supply the polymer liquid to the wafer placed on the plate through the nozzle. Examples in which the polymer liquid is supplied by the polymer coater 100 are described with reference to FIGS. 2, 3, 4A, and 4B.

The wafer to which the polymer liquid has been applied may be transferred to the curer 200 by the wafer transferor 700. The curer 200 may induce curing of the polymer liquid applied to the wafer. For example, the curer 200 may irradiate light onto the surface of the wafer to which the polymer liquid is applied, and/or may heat the surface of the wafer. Accordingly, curing of the polymer liquid may be induced so that a polymer layer may be formed on the insulating film of the wafer.

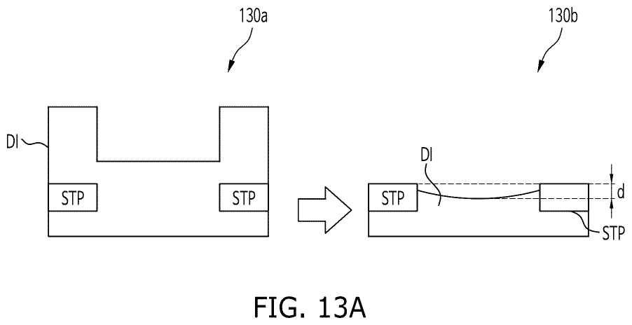

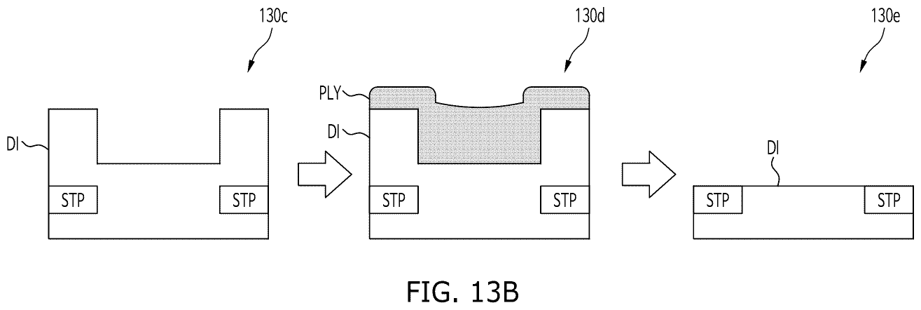

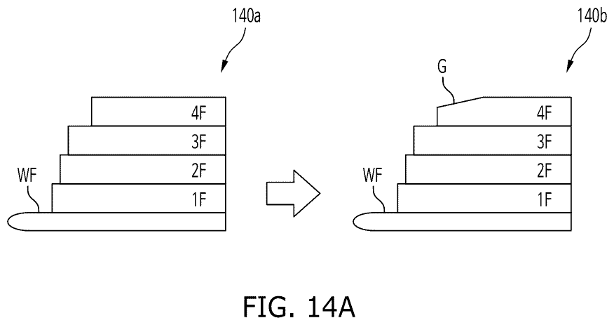

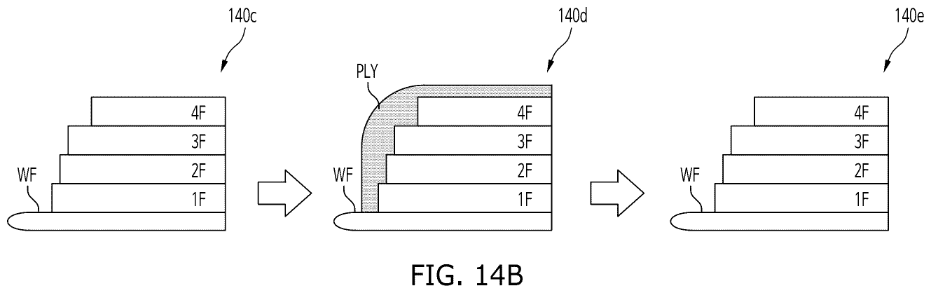

The wafer on which the polymer layer is formed may be transferred to the polisher 300 by the wafer transferor 700. The polisher 300 may polish the surface of the wafer on which the polymer layer is formed. Accordingly, at least a portion of the polymer layer formed on the insulating film of the wafer and at least a portion of the insulating film covering the pattern of the wafer may be polished. Examples in which the wafer is polished are described with reference to FIGS. 13A, 13B, 14A, and 14B.

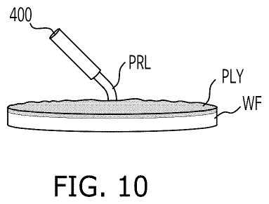

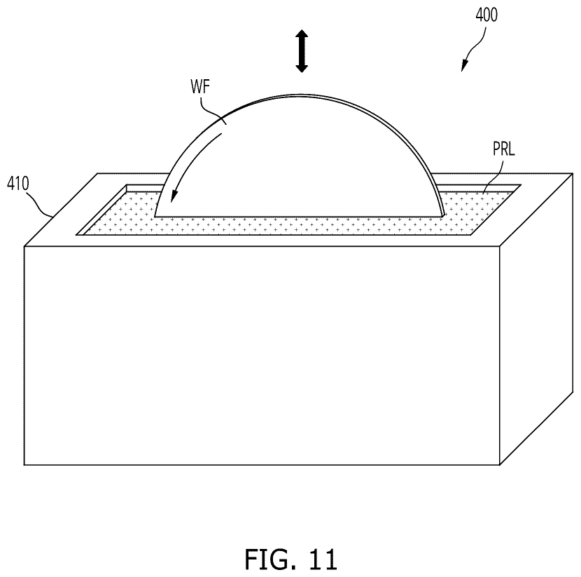

The polished wafer may be transferred to the polymer remover 400 by the wafer transferor 700. The polymer remover 400 may remove any residue of the polymer layer remaining on the surface of the wafer for which the polishing process is completed. For example, the polymer remover 400 may remove the residue of the polymer layer by spraying a polymer removal liquid onto the wafer. As another example, the polymer remover 400 may remove the residue of the polymer layer by immersing the wafer in a polymer removal liquid. In the polymer remover 400, the residue of the polymer layer may be removed while the insulating film of the wafer remains without being removed. Examples in which the residue of the polymer layer is removed by the polymer remover 400 are described with reference to FIGS. 10 and 11.

The wafer from which the residue of the polymer layer is removed may be transferred to the cleaner 500 by the wafer transferor 700. The cleaner 500 may clean foreign matter attached to the surface of the wafer and/or the polymer removal liquid remaining on the surface of the wafer. The cleaned wafer may be transferred out of the chemical mechanical polishing device 10 by the substrate transfer module 600.

The chemical mechanical polishing device 10 may perform processing on a plurality of wafers in parallel. For example, while the polymer coater 100 performs a polymer coating process on a first wafer, the curer 200 may perform a curing process on a second wafer different from the first wafer. In addition, the polymer coater 100 may include a plurality of sub-polymer coaters, and while a first sub-polymer coater performs a polymer coating process on a first wafer, a second sub-polymer coater may perform a polymer coating process on a second wafer. Accordingly, the efficiency of the wafer processing operation by the chemical mechanical polishing device 10 may be increased, when compared to related chemical mechanical polishing devices.

Although FIG. 1 illustrates the polymer coater 100 and the curer 200 as separate devices, and each of the polisher 300 and the polymer remover 400 as including a plurality of sub-devices, embodiments of the present disclosure are not limited thereto. That is, the number and/or arrangement of devices of the chemical mechanical polishing device 10 shown in FIG. 1 are provided as an example. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices.

Although FIG. 1 illustrates the substrate transfer module 600 and the wafer transferor 700 as separate operating elements, embodiments of the present disclosure are not limited thereto. For example, the substrate transfer module 600 may operate as part of the wafer transferor 700.

FIG. 2 illustrates a polymer coater 100, according to an embodiment. Referring to FIG. 2, the polymer coater 100 may include and/or may be similar in many respects to the polymer coater 100 described above with reference to FIG. 1, and may include additional features not mentioned above. Consequently, repeated descriptions of the polymer coater 100 described above with reference to FIG. 1 may be omitted for the sake of brevity.

A first example 20a illustrates an example in which the polymer liquid PL is supplied onto the surface of a wafer, and a second example 20b illustrates an example in which the polymer liquid PL is applied onto the surface of the wafer.

Referring to the first example 20a, the polymer coater 100 may include a plate 110 and a nozzle 120. The plate 110 may be configured to support the wafer. The wafer may include an insulating film formed on the surface thereof. The plate 110 may be configured to support the other surface of the wafer, which may be opposite the surface on which the insulating film is formed.

The polymer coater 100 may supply the polymer liquid PL to the wafer through the nozzle 120. The polymer liquid PL may be supplied onto the surface of the wafer, on which the insulating film is formed, through the nozzle 120. For example, the nozzle 120 may be disposed above the plate 110, and the polymer liquid PL may be sprayed onto the surface of the wafer through the nozzle 120.

In an embodiment, the polymer liquid PL may be supplied to a specific region of the surface of the wafer. For example, the nozzle 120 may be disposed at a fixed position above the plate 110, and may be configured to spray the polymer liquid PL onto a specific region of the surface of the wafer. However, embodiments of the present disclosure are not limited thereto. Although FIG. 2 shows the nozzle 120 positioned at the center of the wafer, the position of the nozzle 120 is not limited thereto and may be changed depending on the type of the wafer and/or the shape of the pattern formed on the surface of the wafer.

In an embodiment, the plate 110 may be configured to rotate about an axis X perpendicular to the surface on which the wafer is placed. In such a case, the polymer liquid PL supplied onto the surface of the wafer may be distributed on the surface of the wafer by a centrifugal force generated by the rotation of the plate 110. Accordingly, as shown in the second example 20b, the polymer liquid PL may be evenly applied onto the surface of the wafer.

In the second example 20b, the polymer liquid PL is shown as being applied only to the surface of the wafer. However, embodiments of the present disclosure are not limited thereto, and the polymer liquid PL may be applied so as to cover both the surface and a side surface of the wafer in their entirety.

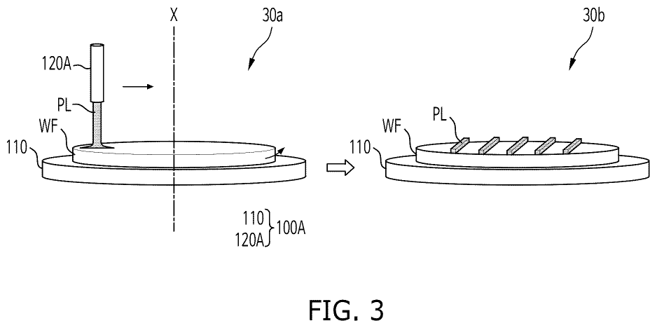

FIG. 3 illustrates a polymer coater, according to an embodiment. Referring to FIG. 3, the polymer coater 100A may include and/or may be similar in many respects to the polymer coaters 100 described above with reference to FIGS. 1 and 2, and may include additional features not mentioned above. Furthermore, the nozzle 120A may include and/or may be similar in many respects to the nozzle 120 described above with reference to FIG. 2, and may include additional features not mentioned above. Consequently, repeated descriptions of the polymer coater 100A described above with reference to FIGS. 1 and 2 may be omitted for the sake of brevity.

A first example 30a illustrates an example in which the polymer liquid PL is supplied onto the surface of the wafer, and a second example 30b illustrates an example in which the polymer liquid PL is applied onto the surface of the wafer.

Referring to the first example 30a, the nozzle 120A may be configured to move above the plate 110. For example, the nozzle 120A may spray the polymer liquid PL while moving above the plate 110. Accordingly, the nozzle 120A may move while selectively spraying the polymer liquid PL onto a specific region of the surface of the wafer. In such a case, depending on the moving path of the nozzle 120A, the polymer liquid PL may be applied onto the surface of the wafer in a predetermined specific pattern. Although FIG. 3 illustrates an example in which the nozzle 120A moves in a direction parallel to the surface of the wafer, embodiments of the present disclosure are not limited thereto. For example, the moving direction of the nozzle 120A may vary based on design constraints.

In an embodiment, the plate 110 may be configured to rotate about an axis X perpendicular to the surface on which the wafer is placed. In such a case, by the combination of the movement of the nozzle 120A and the rotation of the plate 110 (shown as an arrow in FIG. 3), the polymer liquid PL may be applied onto the surface of the wafer in a predetermined specific pattern.

Although the nozzle 120A of FIG. 3 is described as spraying the polymer liquid PL while moving above the plate 110, embodiments of the present disclosure are not limited thereto. For example, in an embodiment, the position of the nozzle 120A may be fixed, and the plate 110 on which the wafer is placed may move and/or rotate below the nozzle 120A, so that the polymer liquid PL may be applied in a specific pattern onto the surface of the wafer. That is, the polymer liquid PL may be applied in a specific pattern onto the surface of the wafer by moving at least one of the nozzle 120A and the plate 110 with respect to each other.

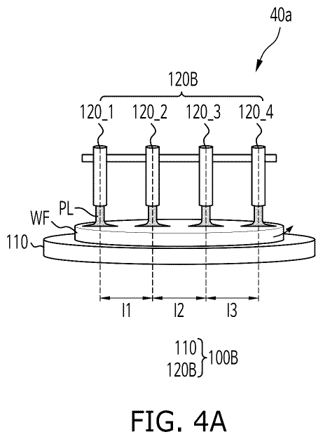

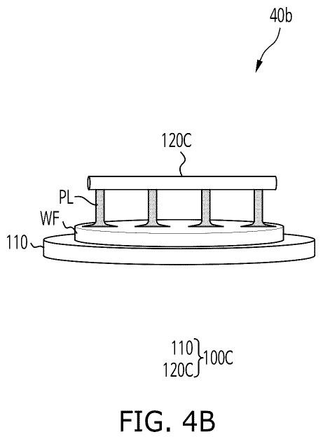

FIGS. 4A and 4B illustrate polymer coaters, according to an embodiment. Referring to FIGS. 4A and 4B, the polymer coaters 100B and 100C may include and/or may be similar in many respects to the polymer coaters 100 and 100A described above with reference to FIGS. 1-3, and may include additional features not mentioned above. Furthermore, the nozzles 120B and 120C may include and/or may be similar in many respects to the nozzles 120 and 120A described above with reference to FIGS. 2 and 3, and may include additional features not mentioned above. Consequently, repeated descriptions of the polymer coaters 100B and 100C described above with reference to FIGS. 1-3 may be omitted for the sake of brevity.

A first example 40a, as shown in FIG. 4A, and a second example 40b, as shown in FIG. 4B, each illustrate an example in which the polymer liquid PL is supplied onto the surface of the wafer.

Referring to the first example 40a of FIG. 4A, the nozzle 120B of the polymer coater 100B may include a plurality of sub-nozzles (e.g., a first sub-nozzle 120_1, a second sub-nozzle 120_2, a third sub-nozzle 120_3, and a fourth sub-nozzle 120_4). The nozzle 120B may apply the polymer liquid PL onto the surface of the wafer placed on the plate 110 through the plurality of sub-nozzles 120_1 to 120_4. Although the first example 40a illustrates the nozzle 120B as including four (4) sub-nozzles 120_1 to 120_4, the number and shapes of the sub-nozzles embodiments of the present disclosure are not limited thereto. For example, the plurality of sub-nozzles 120_1 to 120_4 may include five (5) or more nozzles or may include three (3) or less nozzles. As another example, the plurality of sub-nozzles 120_1 to 120_4 may each have a same shape or may have different shapes from each other.

In an embodiment, intervals (e.g., a first interval l1, a second interval l2, and a third interval l3) between each of the plurality of sub-nozzles 120_1 to 120_4, and/or positions of each of the plurality of sub-nozzles 120_1 to 120_4, may vary depending on the type of the wafer. For example, the intervals l1 to l3 between each of the plurality of sub-nozzles 120_1 to 120_4, and/or the positions of each of the plurality of sub-nozzles 120_1 to 120_4, may be determined based on the shape and/or size of a plurality of chips included in the wafer. As another example, the intervals l1 to l3 between each of the plurality of sub-nozzles 120_1 to 120_4, and/or the positions of each of the plurality of sub-nozzles 120_1 to 120_4, may be determined based on the size of a shot in a photolithography process for the wafer. As another example, the intervals l1 to l3 between each of the plurality of sub-nozzles 120_1 to 120_4, and/or the positions of each of the plurality of sub-nozzles 120_1 to 120_4, may vary depending on the diameter of the wafer and/or the shape of the pattern on the surface of the wafer. Additionally or alternatively, each of the plurality of sub-nozzles 120_1 to 120_4 may be controlled to change position while individually moving in the course of applying the polymer liquid PL. However, embodiments of the present disclosure are not limited thereto.

In an embodiment, the polymer coater 100 may supply the polymer liquid PL onto the surface of the wafer through at least some of the plurality of sub-nozzles 120_1 to 120_4. For example, depending on the type of the wafer, at least one of the plurality of sub-nozzles 120_1 to 120_4 for supplying the polymer liquid PL may be selected. Furthermore, the amount of the polymer liquid PL supplied through each of the plurality of sub-nozzles 120_1 to 120_4 may be individually controlled. However, embodiments of the present disclosure are not limited thereto.

Referring to the second example 40b of FIG. 4B, the polymer coater 100C may include a bar-type nozzle 120C. The nozzle 120C may include a plurality of spray holes through which the polymer liquid PL may be sprayed, and the polymer liquid PL may be supplied onto the surface of the wafer through the plurality of spray holes. Similar to the description of the first example 40a above, at least some of the plurality of spray holes for supplying the polymer liquid PL and/or the amount of the polymer liquid PL supplied through each spray hole may vary depending on the type of the wafer and/or the pattern on the surface of the wafer.

According to embodiments of the present disclosure, the polymer coater 100 may apply the polymer liquid PL onto a plurality of chips on the surface of the wafer by using the plurality of sub-nozzles 120_1 to 120_4. Accordingly, the efficiency of the polymer coating process may be increased, when compared to related chemical mechanical polishing devices.

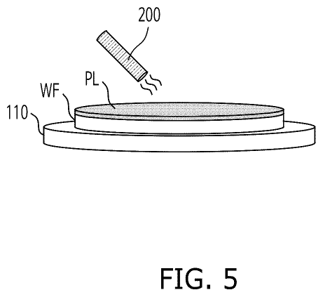

FIG. 5 illustrates a curer 200, according to an embodiment. Referring to FIG. 5, the curer 200 may include and/or may be similar in many respects to the curer 200 described above with reference to FIG. 1, and may include additional features not mentioned above. Consequently, repeated descriptions of the curer 200 described above with reference to FIG. 1 may be omitted for the sake of brevity.

The curer 200 may induce thermal curing of the polymer liquid PL. The polymer liquid PL may be thermally cured by the curer 200, thereby forming a polymer layer on the insulating film of the wafer.

In an embodiment, the curer 200 may apply heat to the polymer liquid PL applied onto the surface of the wafer. The polymer liquid PL may include a thermosetting resin. Accordingly, the polymer liquid PL may undergo cross-linking by thermal energy transferred from the curer 200, thereby forming a polymer layer. For example, the curer 200 may include an infrared light-emitting diode (LED) device. However, embodiments of the present disclosure are not limited thereto.

In an embodiment, the curer 200 may be further configured to treat a surface of the wafer WF. The wafer WF may be and/or may include a wafer before the polymer liquid PL is applied. The curer 200 may heat the surface of the wafer so that the wettability of the surface of the wafer WF is increased, thereby treating a surface of a wafer on which an insulating film is formed, and/or heat the surface of a wafer before the insulating film is formed.

Although FIG. 5 illustrates the curer 200 as including a single heat source, embodiments of the present disclosure are not limited thereto. For example, the curer 200 may include a plurality of sub-curers. Further, intervals between each sub-curer and/or the positions of each of the plurality of sub-curers may vary depending on the type of the wafer. For example, intervals between each sub-curer and/or the positions of each of the plurality of sub-curers may vary depending on the shape and/or size of a plurality of chips included in the wafer, the shape and/or size of a plurality of shots, or the like.

Although FIG. 5 illustrates the curer 200 as being disposed above the plate 110 and applying heat to the surface of the wafer placed on the plate 110, embodiments of the present disclosure are not limited thereto. For example, the curer 200 may be disposed below the plate 110 and heat the wafer through the plate 110. In such a case, the plate 110 may be made of a thermally conductive material. However, embodiments of the present disclosure are not limited thereto.

Referring to FIG. 5, the plate 110 may include and/or may be similar in many respects to the plate 110 described above with reference to FIGS. 1, 2, 3, 4A, and 4B, and may include additional features not mentioned above. Consequently, repeated descriptions of the plate 110 described above with reference to FIGS. 1, 2, 3, 4A, and 4B may be omitted for the sake of brevity.

For example, in a state in which the wafer is placed on the plate 110, the polymer liquid PL coating process and the curing process may be performed sequentially. However, embodiments of the present disclosure are not limited thereto, and the curer 200 may include a separate plate different from the plate 110 of the polymer coater. In such a case, the wafer for which the polymer liquid PL coating process has been completed may be transferred from the plate 110 of the polymer coater to the plate of the curer 200 by a wafer transferor (e.g., the wafer transferor 700 shown in FIG. 1).

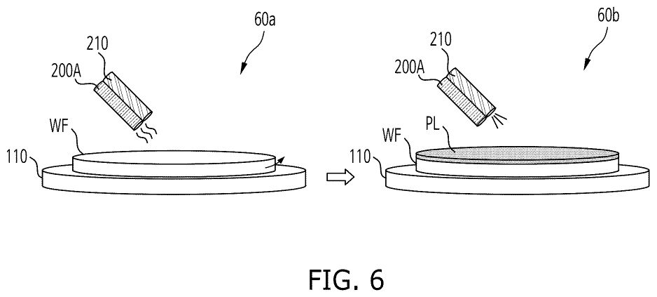

FIG. 6 illustrates a curer, according to an embodiment. Referring to FIG. 6, the curer 200A may include and/or may be similar in many respects to the curers 200 described above with reference to FIGS. 1-3, 4A, 4B, and 5, and may include additional features not mentioned above. Consequently, repeated descriptions of the curer 200A described above with reference to FIGS. 1-3, 4A, 4B, and 5 may be omitted for the sake of brevity.

The curer 200A may induce photo-curing of the polymer liquid PL. The polymer liquid PL may be photo-cured by the curer 200A, thereby forming a polymer layer on the insulating film of the wafer WF.

In an embodiment, the curer 200A may irradiate light onto the polymer liquid PL applied onto the surface of the wafer WF. The polymer liquid PL may include a photo-curable resin. Accordingly, the polymer liquid PL may undergo cross-linking by light energy transferred from the curer 200A, forming a polymer layer. For example, the curer 200A may include an ultraviolet (UV) lamp. However, embodiments of the present disclosure are not limited thereto.

In an embodiment, the curer 200A may be and/or may include a curer of a photo-curing type and the chemical mechanical polishing device 10 may further include a surface treater (or surface treatment device) 210. Referring to the first example 60a, the surface treater 210 may apply heat to the surface of the wafer onto which the polymer liquid PL is not yet applied, thereby treating the surface. Thereafter, the polymer coater 200A may apply the polymer liquid PL onto the surface of the wafer WF. Referring to the second example 60b, the curer 200A may irradiate light onto the polymer liquid PL applied onto the surface of the wafer, thereby inducing curing of the polymer liquid PL. In such a case, the surface treater 210 may further be configured to induce curing of the polymer liquid PL in conjunction with the curer 200A by applying heat to the surface of the wafer on which the polymer liquid PL is applied.

Although FIG. 6 illustrates the curer 200A and the surface treater 210 disposed adjacent to each other above the plate 110 on which the wafer WF is placed, embodiments of the present disclosure are not limited thereto. For example, the curer 200A and the surface treater 210 may be disposed spaced apart from each other above the plate 110.

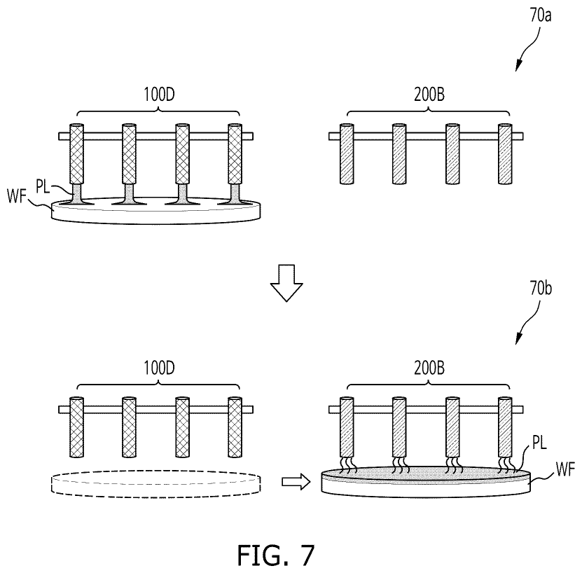

FIG. 7 is a diagram illustrating an example in which a polymer coating process and a curing process are performed, according to an embodiment. Referring to FIG. 7, a first example 70a in which the polymer coater 100 performs the polymer liquid PL coating process, and a second example 70b in which the curing process for the polymer liquid PL applied onto the surface of the wafer is performed, are illustrated. As shown in FIG. 7, the polymer coating process and the curing process may be performed at separate stations.

The polymer coater 100D of FIG. 7 may include and/or may be similar in many respects to the polymer coaters 100, 100A, 100B, and 100C described above with reference to FIGS. 1-3, 4A, and 4B, and may include additional features not mentioned above. Furthermore, the curer 200B of FIG. 7 may include and/or may be similar in many respects to the curers 200 and 200A described above with reference to FIGS. 1, 5, and 6, and may include additional features not mentioned above. Consequently, repeated descriptions of the polymer coater 100D and the curer 200B described above with reference to FIGS. 1-3, 4A, 4B, 5, and 6 may be omitted for the sake of brevity.

In an embodiment, the polymer coating process and the curing process may be performed sequentially. The polymer coating process may be performed at a first station where the polymer coater 100D may be located. The polymer coater 100D may apply the polymer liquid PL onto the surface of the wafer WF. A wafer transferor (e.g., the wafer transferor 700 shown in FIG. 1) may transfer the wafer on which the polymer coating process is completed to a second station where the curer 200B is located. That is, the locations of the polymer coater 100D and the curer 200B may be fixed, and as the wafer WF is moved from the first station to the second station by the wafer transferor, the polymer coating process and the curing process may be performed sequentially.

For example, the wafer transferor may transfer the wafer WF, which may be placed on a plate of the polymer coater 100D (e.g., the plate 110 in FIG. 2), to a plate of the curer 200B. That is, the wafer WF for which the polymer coating process has been completed may be placed on the plate of the curer 200B.

As another example, the wafer transferor may transfer the plate of the polymer coater 100D itself, on which the wafer WF is placed, to the curer 200B. In such a case, the wafer WF may be transferred to the curer 200B while being placed on the plate of the polymer coater 100D.

The polymer liquid PL applied onto the surface of the wafer transferred to the curer 200B may be cured by the curer 200B.

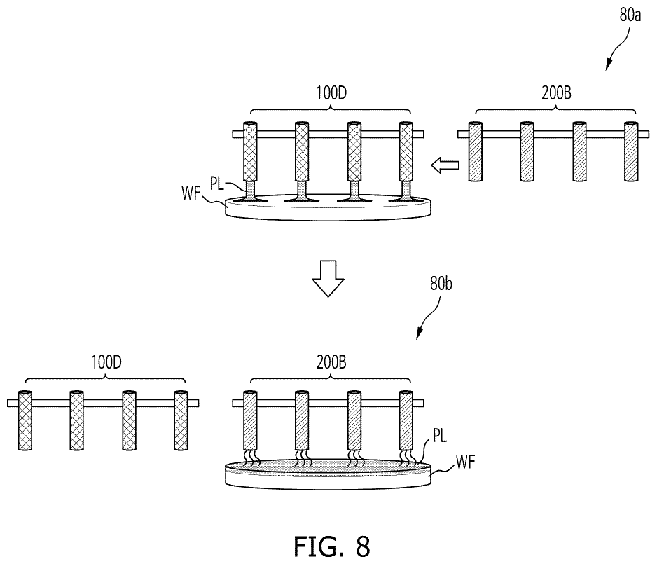

FIG. 8 is a diagram illustrating an example in which a polymer coating process and a curing process are performed, according to an embodiment. Referring to FIG. 8, a first example 80a in which the polymer coater 100D performs the polymer liquid PL coating process, and a second example 80b in which the curing process for the polymer liquid PL applied onto the surface of the wafer WF is performed, are illustrated.

The polymer coater 100D and the curer 200B of FIG. 8 may include and/or may be similar in many respects to the polymer coater 100D and the curer 200B described above with reference to FIG. 7, respectively, and may include additional features not mentioned above. Consequently, repeated descriptions of the polymer coater 100D and the curer 200B described above with reference to FIG. 7 may be omitted for the sake of brevity.

As shown in FIG. 8, the polymer coating process and the curing process may be performed at a single station. For example, the polymer coater 100D may apply the polymer liquid PL onto the surface of the wafer WF. After the polymer coating process is completed, a wafer transferor (e.g., the wafer transferor 700 shown in FIG. 1) may transfer the curer 200B toward the wafer. That is, the position of the wafer WF may be fixed, and as the curer 200B may be moved by the wafer transferor, the polymer coating process and the curing process may be performed in sequence at a single station.

In an embodiment, the wafer transferor 700 may be configured to transfer both the polymer coater 100D and the curer 200B. In such a case, the polymer coating process and the curing process for a plurality of wafers WF may be performed continuously. For example, while the curing process for a first wafer is being performed, the polymer coating process for a second wafer may be performed. When the polymer coating process for the second wafer is completed, the polymer coater 100D may be transferred to a third wafer, and the curer 200B may be transferred to the second wafer. Accordingly, the curing process for the second wafer and the polymer coating process for the third wafer may be performed consecutively.

As another example, the wafer transferor 700 may transfer only the curer 200B. For example, when the polymer coating process for the wafer WF is completed, the wafer transferor 700 may transfer the curer 200B toward the wafer WF while keeping the position of the polymer coater 100D fixed.

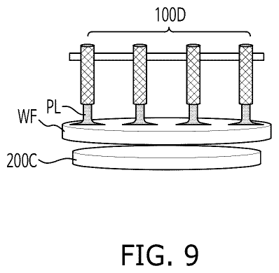

FIG. 9 is a diagram illustrating an example in which a polymer coating process and a curing process are performed, according to an embodiment. Referring to FIG. 9, the polymer coating process and the curing process may be performed at a single station.

The polymer coater 100D of FIG. 9 may include and/or may be similar in many respects to the polymer coater 100D described above with reference to FIGS. 7 and 8, and may include additional features not mentioned above. Furthermore, the curer 200C of FIG. 9 may include and/or may be similar in many respects to the curers 200, 200A, and 200B described above with reference to FIGS. 1 and 5-8, and may include additional features not mentioned above. Consequently, repeated descriptions of the polymer coater 100D and the curer 200C described above with reference to FIGS. 1 and 5-8 may be omitted for the sake of brevity.

Referring to FIG. 9, the polymer coater 100D and the curer 200C may be arranged at a single station. For example, the polymer coater 100D may be disposed above the plate on which the wafer is placed, and the curer 200C may be disposed below the plate on which the wafer is placed. However, embodiments of the present disclosure are not limited thereto. For example, both the polymer coater 100D and the curer 200C may be disposed above the plate on which the wafer is placed. As another example, the curer 200C may be formed integrally with the plate. When the polymer coating process is completed by the polymer coater 100D, the curer 200C may apply heat to the wafer on which the polymer liquid PL is applied, inducing curing of the polymer liquid PL.

In an embodiment, when both the polymer coating process and the curing process are completed, a wafer transferor (e.g., the wafer transferor 700 shown in FIG. 1) may transfer the wafer WF. For example, the wafer transferor 700 may transfer the wafer WF from a first station, where the polymer coater 100D and the curer 200C may be located, to a second station where a device for performing a subsequent process (e.g., the polisher 300 shown in FIG. 1) may be arranged.

In an embodiment, when both the polymer coating process and the curing process are completed, a wafer transferor (e.g., the wafer transferor 700 shown in FIG. 1) may transfer both the polymer coater 100D and the curer 200C. For example, the wafer transferor 700 may transfer both the polymer coater 100D and the curer 200C to a second wafer in order to perform the polymer coating process for the second wafer, when both the polymer coating process and the curing process for a first wafer have been completed.

The examples of how the polymer coating process and the curing process may be performed sequentially, as described with reference to FIGS. 7-9, are not limited thereto, and may vary depending on the arrangement of the internal components of the chemical mechanical polishing device 10, the number of wafers that the chemical mechanical polishing device 10 may process simultaneously, or the like.

FIG. 10 illustrates a polymer remover 400, according to an embodiment. In an embodiment, the wafer WF for which the polishing process is completed by the polisher (e.g., the polisher 300 shown in FIG. 1) may be transferred to the polymer remover 400. The wafer WF for which the polishing process is completed may be in a state in which at least some of an insulating film formed on the surface of the wafer and/or at least some of a polymer layer PLY formed by the curing of the polymer liquid PL applied onto the insulating film has been removed by the polishing process. The polymer remover 400 may be configured to remove a residue of the polymer layer PLY remaining on the surface of the polished wafer.

The polymer remover 400 may include a nozzle for supplying a polymer removal liquid PRL. The polymer remover 400 may spray the polymer removal liquid PRL onto the surface of the wafer through the nozzle.

In an embodiment, the polymer forming the polymer layer PLY may include a temperature-dependent polymer with physical and/or chemical properties that may change according to changes in temperature. In such a case, the polymer removal liquid PRL may be and/or may include a cleaning liquid within a specific temperature range, configured to melt the residue of the polymer layer PLY. The cleaning liquid may include high-temperature deionized water (DIW). However, embodiments of the present disclosure are not limited thereto.

In an embodiment, the polymer forming the polymer layer PLY may include a pH-dependent polymer with physical and/or chemical properties that may change under a specific pH condition. In such a case, the polymer removal liquid PRL may be and/or may include a cleaning liquid within a specific pH range, configured to melt the residue of the polymer layer PLY. Alternatively or additionally, the polymer removal liquid PRL may remove the residue of the polymer layer PLY through a chemical reaction with the polymer forming the polymer layer PLY.

In an embodiment, the polymer remover 400 may be configured to remove the residue of the polymer layer PLY without leaving any residue behind. Accordingly, a problem in which the quality of the product is degraded by an uneven surface of the wafer WF caused by the residue of the polymer layer PLY, or in which a defect is caused in a subsequent process by the residue of the polymer layer PLY, may be prevented and/or reduced, when compared to related chemical mechanical polishing devices. The polymer removal liquid PRL may be and/or may include an alkaline aqueous solution. The polymer removal liquid PRL may remove the residue of the polymer layer PLY while not removing the insulating film of the wafer.

FIG. 11 illustrates a polymer remover 400, according to an embodiment. In an embodiment, the wafer for which the polishing process is completed by the polisher (e.g., the polisher 300 shown in FIG. 1) may be transferred to the polymer remover 400.

In an embodiment, the polymer remover 400 may include a receiving part 410 in which a polymer removal liquid PRL may be received. For example, the receiving part 410 may be in the form of a container having an open top surface and having an internal space for receiving the polymer removal liquid PRL.

In an embodiment, the polymer remover 400 may further include a wafer transferor for moving the wafer WF. The wafer transferor may be substantially similar and/or the same as, or at least part of, the wafer transferor 700 shown in FIG. 1. The wafer transferor may move the wafer WF into or out of the receiving part 410 so that at least part of the wafer WF may be immersed in the polymer removal liquid PRL. For example, the wafer transferor may move the wafer WF downward inside the receiving part 410 through the open top surface of the receiving part 410 so that at least part of the wafer is brought into the receiving part 410. Additionally or alternatively, the wafer transferor may move the wafer WF upward out of the receiving part 410 through the open top surface of the receiving part 410 so as to withdraw the wafer WF from the receiving part 410. Furthermore, while the wafer WF is immersed in the polymer removal liquid PRL, the wafer transferor may rotate the wafer WF, thereby effectively removing the residue of the polymer layer.

In an embodiment, the polymer remover 400 may further include a solution supply device for supplying the polymer removal liquid PRL into the receiving part 410, a solution discharge device for discharging the contaminated polymer removal liquid PRL from the receiving part 410, or the like.

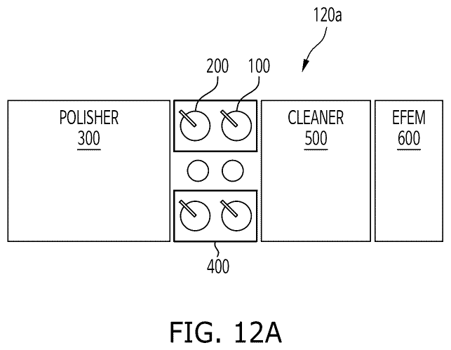

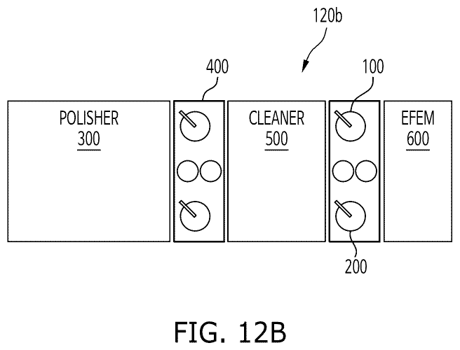

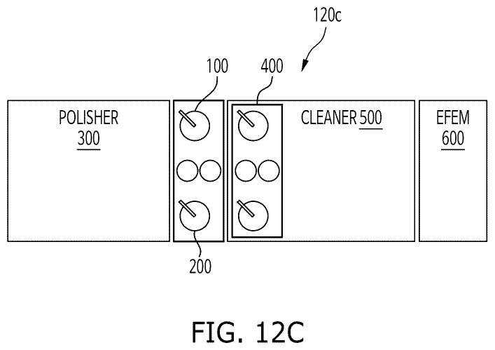

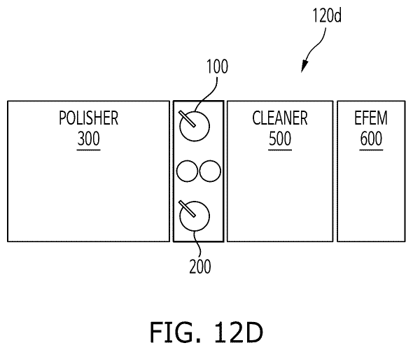

FIGS. 12A, 12B, 12C, and 12D are diagrams illustrating example arrangements of internal components of a chemical mechanical polishing device, according to an embodiment. Referring to FIGS. 12A, 12B, 12C, and 12D, various examples in which internal components of the chemical mechanical polishing device 10 (e.g., the polymer coater 100, the curer 200, the polisher 300, the polymer remover 400, the cleaner 500, and the substrate transfer module 600) are arranged.

A wafer transferred into the chemical mechanical polishing device 10 by the substrate transfer module 600 may be sequentially transferred to the polymer coater 100, the curer 200, the polisher 300, the polymer remover 400, and the cleaner 500 by a wafer transferor. For example, the wafer transferred into the chemical mechanical polishing device 10 may be transferred to the polymer coater 100, where the polymer liquid PL is applied. The wafer to which the polymer liquid PL is applied may be transferred to the curer 200 so that curing of the polymer liquid PL is induced. Subsequently, the wafer, on which the polymer liquid PL has been cured to form a polymer layer, may be transferred to the polisher 300 to be polished. In addition, the polished wafer may be transferred to the polymer remover 400 so that the residue of the polymer layer may be removed. The wafer from which the residue of the polymer layer has been removed may be transferred to the cleaner 500 for cleaning.

Referring to the first example 120a, as shown in FIG. 12A, the polymer coater 100 and the curer 200 may be arranged between the polisher 300 and the cleaner 500. In such a case, the wafer transferred into the chemical mechanical polishing device 10 through the substrate transfer module 600 may pass through the cleaner 500 and be transferred to the polymer coater 100. In the course of passing through the cleaner 500, the wafer may come into contact with a cleaning liquid and the surface of the wafer may be in a wet state. In such a case, the polymer liquid PL to be applied in the polymer coater 100 may be determined to be a polymer liquid PL suitable for application to a wet surface of the wafer.

Referring to the second example 120b, as shown in FIG. 12B, the polymer coater 100 may be arranged adjacent to the substrate transfer module 600. In such a case, the polymer coater 100 may be arranged between the substrate transfer module 600 and the cleaner 500. In such a case, the wafer transferred into the chemical mechanical polishing device 10 through the substrate transfer module 600 may be transferred directly to the polymer coater 100 without going through the cleaner 500. In such a case, the polymer liquid PL to be applied in the polymer coater 100 may be determined to be a polymer liquid PL suitable for application to a dry surface of the wafer.

Referring to the third example 120c, as shown in FIG. 12C, the polymer remover 400 may be disposed inside the cleaner 500 as part of the cleaner 500.

Referring to the fourth example 120d, as shown in FIG. 12D, the polymer remover 400 may be omitted, and the cleaner 500 may perform the function of the polymer remover 400 as well. In such a case, the nozzle for spraying the polymer removal liquid PRL and the cleaning liquid may be shared, and each liquid and/or solution may be sprayed sequentially and/or simultaneously (e.g., at substantially the same time). Accordingly, the wafer processing may be simplified, increasing space efficiency, and unnecessary wafer movement may be reduced, thereby enhancing the efficiency of the wafer processing, when compared to related chemical mechanical polishing devices.

FIG. 13A is a diagram illustrating an example of a wafer processed by a chemical mechanical polishing device 10, according to a comparative example. FIG. 13B is a diagram illustrating an example of a wafer processed by a chemical mechanical polishing device, according to an embodiment.

Referring to FIG. 13A, a first cross-sectional schematic diagram 130a and a second cross-sectional schematic diagram 130b illustrate a wafer being processed in a state in which no polymer liquid PL is applied to the surface of the wafer.

Referring to the first cross-sectional schematic diagram 130a, the wafer may include an insulating film DI and a stopper STP. The insulating film DI may be configured to fill a space between patterns and/or to cover an upper side of a pattern so as to provide electrical insulation between patterns formed on the surface of the wafer. The stopper STP may be arranged at a specific height on the surface of the wafer and may be configured to prevent a specific layer of the wafer from being over-polished.

The second cross-sectional schematic diagram 130b shows a wafer in a state in which a polishing process has been performed. As shown in FIG. 13A, a dishing phenomenon may occur in which a height difference d may arise between a region where the stopper STP is arranged and a region filled with the insulating film DI between the stoppers STP. Such a dishing phenomenon may occur when a region having a relatively high polish rate (e.g., the region where the insulating film DI is filled) may be excessively removed and may become recessed, thereby reducing the planarity of the wafer surface and potentially causing, for example, deterioration in the uniformity of the wafer, and/or deterioration of electrical characteristics of metal wiring in subsequent processes.

Referring to FIG. 13B, a third cross-sectional schematic diagram 130c, a fourth cross-sectional schematic diagram 130d, and a fifth cross-sectional schematic diagram 130e illustrate a wafer being processed in a state in which a polymer liquid PL has been applied onto the insulating film DI formed on the surface of the wafer so that a polymer layer PLY is formed.

Referring to the cross-sectional schematic diagram 130d, the polymer layer PLY may be formed on the insulating film Dl of the wafer. The polymer layer PLY may be designed to reinforce the region having a relatively low strength during the wafer polishing process. The polymer layer PLY may function as a sacrificial layer for the region having a relatively low strength, thereby ensuring the planarity of the wafer and improving the quality in subsequent processes, when compared to related chemical mechanical polishing devices.

Referring to the fifth cross-sectional schematic diagram 130e, a height difference may not occur between the region where the stopper STP may be arranged and the region filled with the insulating film DI between the stoppers STP.

FIG. 14A is a diagram illustrating an example of a wafer processed by a chemical mechanical polishing device 10, according to a comparative example. FIG. 14B is a diagram illustrating an example of a wafer processed by a chemical mechanical polishing device 10, according to an embodiment.

Referring to FIG. 14A, a first cross-sectional schematic diagram 140a and a second cross-sectional schematic diagram 140b illustrate of a wafer WF being processed in a state in which no polymer liquid PL is applied to the surface of the wafer WF.

Referring to the first cross-sectional schematic diagram 140a, the wafer WF may have a structure in which at least one layer is laminated. In this state, when a polishing process is performed on the wafer WF, as shown in the second cross-sectional schematic diagram 140b, an edge portion G of the wafer WF may be excessively polished compared to the central portion of the wafer, thereby degrading the planarity of the surface of the wafer WF. Such a non-uniform surface of the wafer may cause deterioration in the quality of subsequent processes.

Referring to FIG. 14B, a third cross-sectional schematic diagram 140c, a fourth cross-sectional schematic diagram 140d, and a fifth cross-sectional schematic diagram 140e illustrate a wafer WF being processed in a state in which a polymer liquid PL is applied onto the surface of the wafer WF so that a polymer layer PLY is formed. As shown in the fourth cross-sectional schematic diagram 140d and the fifth cross-sectional schematic diagram 140e, if the polymer layer PLY is arranged so as to surround the layers laminated on the wafer WF, it may be possible to prevent the edge portion of the wafer WF from being excessively polished and the surface of the wafer WF from becoming non-uniform.

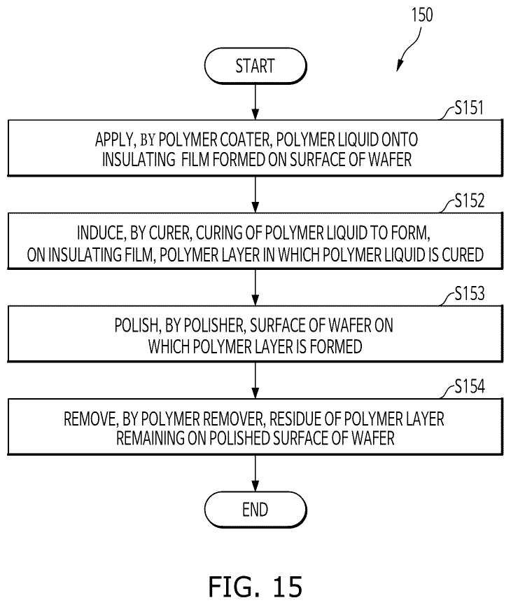

FIG. 15 is a flowchart illustrating a wafer processing method 150, according to an embodiment. The wafer processing method 150 may be performed by the chemical mechanical polishing device 10. The chemical mechanical polishing device 10 may include the polymer coater 100, the curer 200, the polisher 300, the polymer remover 400, the wafer transferor 700, and the cleaner 500. In an embodiment, one or more processors of the chemical mechanical polishing device 10 may execute, individually or collectively, one or more instructions to perform the functionality of the wafer processing method 150. Alternatively or additionally, the chemical mechanical polishing device 10 may perform the functionality of the wafer processing method 150 in conjunction with the polymer coater 100, the curer 200, the polisher 300, the polymer remover 400, the wafer transferor 700, and the cleaner 500.

At block S151, the wafer processing method 150 may include applying, by the polymer coater 100, a polymer liquid PL onto an insulating film formed on the surface of the wafer WF. The polymer coater 100 may include a plate 110 configured to support the wafer WF and a nozzle 120 configured to supply the polymer liquid PL to the wafer WF placed on the plate.

In an embodiment, the plate 110 may be configured to rotate about an axis X perpendicular to the surface on which the wafer WF is placed. As the plate 110 rotates, the polymer liquid PL initially supplied to a specific region on the insulating film may be dispersed and applied onto the insulating film.

In an embodiment, the nozzle 120 may be configured to move above the plate 110. Accordingly, the nozzle 120 may move above the plate 110 so as to apply the polymer liquid PL onto the insulating film in a specific pattern. In addition, the nozzle 120 may include a plurality of nozzles. In such a case, intervals between each of the plurality of nozzles and/or the positions of each of the plurality of nozzles may be adjusted depending on the type of the wafer WF.

At block S152 of the wafer processing method 150, the curer 200 may induce curing of the polymer liquid PL to form a polymer layer in which the polymer liquid PL is cured on the insulating film. For example, when application of the polymer liquid PL is completed by the polymer coater 100, the wafer transferor 700 may transfer the wafer WF to the curer 200. As another example, when application of the polymer liquid PL is completed by the polymer coater 100, the wafer transferor 700 may transfer the curer 200 toward the wafer WF. As another example, the curer 200 may be disposed below the plate 110, and when application of the polymer liquid PL is completed by the polymer coater 100, the curer 200 may apply heat to the wafer WF on which the polymer liquid PL is applied.

In an embodiment, the curer 200 may induce curing of the polymer liquid PL by a thermal curing method and/or a photo-curing method. For example, the curer 200 may apply heat to the polymer liquid PL applied onto the insulating film, thereby inducing thermal curing of the polymer liquid PL, and/or may irradiate light onto the polymer liquid PL applied onto the insulating film, thereby inducing photo-curing of the polymer liquid PL.

In an embodiment, the curer 200 of a thermal curing method may be further configured to perform a surface treatment on the insulating film. For example, before the polymer liquid PL is applied onto the insulating film by the polymer coater 100, the curer 200 may apply heat to the insulating film on which the polymer liquid PL is not yet applied, thereby treating the surface of the insulating film.

In an embodiment, when a curer 200 of a photo-curing method is used, the chemical mechanical polishing device 10 may further include a surface treater 210 configured to perform a surface treatment on the insulating film. For example, before the polymer liquid PL is applied onto the insulating film by the polymer coater 100, the surface treater 210 may apply heat to the insulating film on which the polymer liquid PL is not yet applied, thereby treating the surface of the insulating film.

In an embodiment, the curer 200 may include a plurality of sub-curers. In such a case, intervals between each of the plurality of sub-curers and/or the positions of each of the plurality of sub-curers may be adjusted depending on the type of the wafer WF.

At block S153, the wafer processing method 150 may include polishing, by the polisher 300, the surface of the wafer WF on which the polymer layer is formed. The wafer transferor 700 may move the wafer WF, on which the polymer layer is formed by curing of the polymer liquid PL, from the curer 200 to the polisher 300.

At block S153, the wafer processing method 150 may include removing, by the polymer remover 400, a residue of the polymer layer remaining on the surface of the polished wafer. For example, the polymer remover 400 may spray a polymer removal liquid PRL onto the surface of the polished wafer. As another example, the polymer remover 400 may include a receiving part configured to receive the polymer removal liquid PRL, and the wafer transferor 700 may bring the polished wafer into or out of the receiving part so that at least part of the polished wafer is immersed in the polymer removal liquid PRL. The residue of the polymer layer remaining on the surface of the polished wafer may be melted by the polymer removal liquid PRL within a specific temperature range and/or may be removed by a chemical reaction with the polymer removal liquid PRL.

The wafer processing method 150 may further include cleaning, by the cleaner 500, the wafer WF from which the residue of the polymer layer has been removed.

The flowchart and the above description with reference to FIG. 15 are merely examples, and may be implemented differently in some embodiments. For example, in some embodiments, the order of each step may be changed, some steps may be repeated, some steps may be omitted, or some steps may be added.

While this invention has been described with reference to illustrative embodiments, this description is not intended to be construed in a limiting sense. Various modifications and combinations of the illustrative embodiments, as well as other embodiments of the invention, may be apparent to persons skilled in the art upon reference to the description. It is therefore intended that the appended claims encompass any such modifications or embodiments.

What is claimed is:

1. A chemical mechanical polishing device, comprising:
a polymer coater configured to apply a polymer liquid onto an insulating film formed on a surface of a wafer;
a curer configured to form a polymer layer on the insulating film by inducing curing of the polymer liquid;
a polisher configured to polish the surface of the wafer on which the polymer layer is formed; and
a polymer remover configured to remove a residue of the polymer layer remaining on the polished surface of the wafer.

2. The chemical mechanical polishing device of claim 1, wherein the polymer coater comprises:
a plate configured to support the wafer; and
a nozzle configured to supply the polymer liquid to the wafer.

3. The chemical mechanical polishing device of claim 2, wherein the plate is further configured to:
rotate about an axis perpendicular to a surface of the plate on which the wafer is placed, and
disperse and apply, as the plate rotates, the polymer liquid onto the insulating film.

4. The chemical mechanical polishing device of claim 2, wherein the nozzle is further configured to:
move above the plate, and
apply the polymer liquid onto the insulating film in a predetermined pattern.

5. The chemical mechanical polishing device of claim 2, wherein the nozzle comprises a plurality of sub-nozzles, and
wherein the nozzle is further configured to adjust, based on a type of the wafer, at least one of intervals between each of the plurality of sub-nozzles or positions of each of the plurality of sub-nozzles.

6. The chemical mechanical polishing device of claim 1, wherein the curer is further configured to:
induce thermal curing of the polymer liquid by applying heat to the polymer liquid applied onto the insulating film.

7. The chemical mechanical polishing device of claim 6, wherein the curer is further configured to:
treat a surface of the insulating film by applying heat to an uncoated portion of the insulating film.

8. The chemical mechanical polishing device of claim 1, wherein the curer is further configured to:
induce photo-curing of the polymer liquid by irradiating light onto the polymer liquid applied onto the insulating film.

9. The chemical mechanical polishing device of claim 8, further comprising:
a surface treater configured to treat a surface of the insulating film by applying heat to an uncoated portion of the insulating film.

10. The chemical mechanical polishing device of claim 1, wherein the curer comprises a plurality of sub-curers, and
wherein the curer is further configured to adjust, based on a type of the wafer, at least one of intervals between each of the plurality of sub-curers or positions of each of the plurality of sub-curers.

11. The chemical mechanical polishing device of claim 1, further comprising:
a wafer transferor configured to transfer the wafer to the curer, based on application of the polymer liquid by the polymer coater being completed.

12. The chemical mechanical polishing device of claim 1, further comprising:
a wafer transferor configured to transfer the curer toward the wafer, based on application of the polymer liquid by the polymer coater being completed.

13. The chemical mechanical polishing device of claim 2, wherein the curer is below the plate, and
wherein the curer is further configured to apply heat to the wafer on which the polymer liquid is applied, based on application of the polymer liquid by the polymer coater being completed.

14. The chemical mechanical polishing device of claim 1, wherein the polymer remover is further configured to:
spray a polymer removal liquid onto the polished surface of the wafer.

15. The chemical mechanical polishing device of claim 14, wherein the polymer remover is further configured to:
melt the residue of the polymer layer remaining on the polished surface of the wafer by the polymer removal liquid at a predetermined temperature range.

16. The chemical mechanical polishing device of claim 15, wherein the polymer remover is further configured to:
remove the residue of the polymer layer remaining on the polished surface of the wafer by a chemical reaction with the polymer removal liquid.

17. The chemical mechanical polishing device of claim 1, further comprising:
a wafer transferor configured to transfer the wafer,
wherein the polymer remover comprises a receiving part configured to receive a polymer removal liquid, and
wherein the wafer transferor is further configured to position at least one portion of the polished wafer within the receiving part and immerse the at least one portion of the polished wafer in the polymer removal liquid.

18. The chemical mechanical polishing device of claim 1, further comprising:
a cleaner configured to clean the wafer from which the residue of the polymer layer has been removed.

19. A chemical mechanical polishing device, comprising:
a polymer coater configured to apply a polymer liquid onto an insulating film formed on a surface of a wafer;
a curer configured to form a polymer layer on the insulating film by inducing curing of the polymer liquid;
a polisher configured to polish the surface of the wafer on which the polymer layer is formed;
a polymer remover configured to remove a residue of the polymer layer remaining on the polished surface of the wafer;
a cleaner configured to clean the wafer from which the residue of the polymer layer has been removed; and
a wafer transferor configured to:
transfer the wafer from the polymer coater to the curer, based on application of the polymer liquid being completed,
transfer the wafer from the curer to the polisher, based on the polymer layer being formed by the curing of the polymer liquid,
transfer the polished wafer from the polisher to the polymer remover, and
transfer the wafer from the polymer remover to the cleaner, based on the residue of the polymer layer being removed.

20. A wafer processing method to be performed chemical mechanical polishing device, comprising:
applying, using a polymer coater of the chemical mechanical polishing device, a polymer liquid onto an insulating film formed on a surface of a wafer;
forming a polymer layer on the insulating film by inducing curing of the polymer liquid using a curer of the chemical mechanical polishing device;
polishing, using a polisher of the chemical mechanical polishing device, the surface of the wafer on which the polymer layer is formed; and
removing, using a polymer remover of the chemical mechanical polishing device, a residue of the polymer layer remaining on the polished surface of the wafer.
